(19) United States
(12) Patent Application Publication
(10) Pub. No.: US 2025/0123575 A1
(43) Pub. Date: Apr. 17, 2025

(54) METHOD FOR HEATING AN OPTICAL ELEMENT, AND OPTICAL SYSTEM

(71) Applicant: Carl Zeiss SMT GmbH, Oberkochen (DE)

(72) Inventors: Malte LANGENHORST, Aalen (DE); Werner WEISS, Ulm (DE); Fabian LETSCHER, Oberkochen (DE); Ruediger MACK, Oberkochen (DE); Lucas TEUBER, Aalen (DE); André DIRAUF, Aalen (DE); Felix WAELDCHEN, Aalen (DE)

(21) Appl. No.: 18/977,419

(22) Filed: Dec. 11, 2024

Related U.S. Application Data
(63) Continuation of application No. PCT/EP2023/065477, filed on Jun. 9, 2023.

(30) Foreign Application Priority Data
Jun. 14, 2022 (DE) 10 2022 114 969.2

(51) Int. Cl. G03F 7/00; G01M 11/02

(52) U.S. Cl. CPC G03F 7/70891; G01M 11/0242; G03F 7/70266; G03F 7/70525; G03F 7/706

(57) ABSTRACT

A method for heating an optical element in an optical system, such as a microlithographic projection exposure system, comprises introducing a heating power into the optical element using a thermal manipulator. The heating power is adjusted to a set of desired values. The set of desired values is adjusted to produce a thermally induced deformation depending on a first optical aberration to be compensated. Adjusting the set of desired values also includes taking into account the effect of introducing the heating power on a second optical aberration which is caused by useful light impinging on the optical element during operation of the optical system. The thermally induced deformation profile can be co-optimized.

### CROSS-REFERENCE TO RELATED APPLICATIONS

The present application is a continuation of, and claims benefit under 35 USC 120 to, international application No. PCT/EP2023/065477, filed Jun. 9, 2023, which claims benefit under 35 USC 119 of German Application No. 10 2022 114 969.2, filed Jun. 14, 2022. The entire disclosure of each of these applications is incorporated by reference herein.

### FIELD

The disclosure relates to a method of heating an optical element in an optical system, such as in a microlithographic projection exposure apparatus, and to an optical system.

### BACKGROUND

Microlithography is used for producing microstructured components, for example integrated circuits or LCDs. The microlithography process is carried out in a so-called projection exposure apparatus comprising an illumination device and a projection lens. The image of a mask (=reticle) illuminated via the illumination device is projected in this case via the projection lens onto a substrate (for example a silicon wafer) that is coated with a light-sensitive layer (photoresist) and arranged in the image plane of the projection lens in order to transfer the mask structure to the light-sensitive coating of the substrate.

In projection lenses designed for the EUV range, i.e. at wavelengths of for example approximately 13 nanometers (nm) or approximately 7 nm, mirrors are used as optical components for the imaging process owing to the general lack of availability of suitable light-transmissive refractive materials.

An issue which can arise in practice is that on account of manufacturing fluctuations of the mirrors and also finite precision of mounting and/or alignment processes to be carried out during assembly of the projection exposure apparatus, unavoidable optical aberrations can result owing to the existence of deviations from the ideal optical design. In order to correct such optical aberrations (also referred to as “cold aberrations”), one possible approach—besides the targeted actuation of the respective mirrors in their rigid body degrees of freedom—is to apply a suitable heating profile to the mirrors in a targeted manner using an (e.g. infrared radiation-based) heating arrangement in order to achieve a correction of the optical cold aberrations using the deformation thermally induced in this way.

Another issue which can arise in practice is that, as a result inter alia of absorption of the radiation emitted by the EUV light source, the EUV mirrors can heat up (also referred to as “mirror heating”) and can undergo an associated thermal expansion or deformation, which in turn can result in an impairment of the imaging properties of the optical system.

In order to avoid surface deformations caused by heat inputs into an EUV mirror, and attendant optical aberrations, it is known inter alia to use a mirror substrate material in the form of an ultra-low expansion material, e.g. a titanium silicate glass sold under the trade name ULE™ by Corning Inc. and to set the so-called zero-crossing temperature (ZCT) in a region near the optical effective surface. At this zero-crossing temperature, which is approximately 9=30° C. for example for ULE™, the coefficient of thermal expansion has in its temperature dependence a zero crossing in the vicinity of which there is no or only a negligible dependence of the thermal expansion of the mirror substrate material on temperature variations that occur. Furthermore, owing to the use of a heating arrangement (e.g. on the basis of infrared radiation), active mirror heating can take place in phases of comparatively low absorption of EUV used radiation, the active mirror heating being correspondingly decreased as the absorption of the EUV used radiation increases.

A further issue that can arise here in practice is that the above-described approaches firstly for correcting “cold aberrations” and secondly for avoiding deformations induced in the respective mirror and the attendant “mirror heating” as a consequence of impingement of EUV or used light during operation of the optical system in this respect can include opposing or conflicting desired properties since—as indicated in the schematic diagram in FIG. 2—the temperature ranges or target values that are expedient or favored in each case differ from one another. For example, in order to avoid optical aberrations thermally induced by EUV radiation during the operation of the optical system, a temperature window in the region of the aforementioned zero-crossing temperature (=ZCT) is desirable, in which arising thermally induced deformations are as insensitive as possible to local temperature variations at different mirror positions. By contrast, for the correction effect sought with regard to the “cold aberrations”, it is generally desirable for the respective mirror to be heated into a temperature range in which the deformation of the mirror is sufficiently sensitive to additional thermal irradiation, as a result of which, however, the aberrations induced as a result of the impingement of EUV light during operation and the influence of “mirror heating” mentioned above are in turn intensified.

Reference is made by way of example to DE 10 2019 219 289 A1.

### SUMMARY

The present disclosure seeks to provide a method for heating an optical element, such as in a microlithographic projection exposure apparatus, and an optical system which can help allow effective avoidance of surface deformations caused by heat inputs in the optical element, and attendant optical aberrations.

According to one aspect, the disclosure relates to a method for heating an optical element in an optical system, such as in a microlithographic projection exposure apparatus,
wherein a heating power is introduced into the optical element using a thermal manipulator, and wherein this heating power is set to a set of target values,
wherein this set of target values for creating a thermally induced deformation is set depending on a first optical aberration to be compensated, and
wherein the set of target values is set with additional consideration being given to the respective effect of the introduction of the heating power on a second optical aberration, which is caused by used light incident on the optical element during the operation of the optical system.

The disclosure is not restricted further with regard to the specific configuration of the thermal manipulator, i.e. the way in which the heating power is introduced into the optical element. Merely by way of example, the heating power can for instance be introduced in a manner known per se via infrared (IR) emitters, wherein for example individual sectors can also be subjected to IR radiation by way of the setting of corresponding heating profiles. For example, a heating arrangement described in DE 10 2019 219 289 A1 can be used for this purpose. Alternatively, the heating power can also be introduced by way of electrodes to which voltage can be applied and which are arranged on the optical element or mirror to be heated.

In this case, the wording “set of target values” is intended to express the fact that the thermal manipulator can optionally also subject individual sectors to IR radiation in a targeted manner by way of the setting of corresponding heating profiles (e.g. using the heating arrangement described in DE 10 2019 219 289 A1). In this respect, the “set of target values” for the heating power of the thermal manipulator optionally comprises in each case a value for each of the sectors (in the manner of a vector having a plurality of components).

According to one embodiment, the first optical aberration is at least partly caused by manufacturing or alignment. Moreover, the first optical aberration may be brought about by the optical element itself or elsewhere in the optical system (e.g. by some other optical element).

The feature or formulation whereby the set of target values for the creation of a thermally induced deformation is set “depending on a first optical aberration to be compensated” should be understood to mean that this also comprises configurations in which the first aberration (e.g. due to manufacture or alignment) is not minimized (i.e. not corrected as completely as possible) but optionally set to a desired (wavefront) signature of the optical system or the projection lens of the projection exposure apparatus in a targeted manner.

The disclosure can involve the concept of setting a heating power introduced by a thermal manipulator into an optical element for the purpose of correcting e.g. manufacturing- or alignment-related optical aberrations (so-called “cold aberrations”) or of defining the corresponding target value or set of target values for setting this heating power not only with regard to these cold aberrations but also with due consideration being given, already during the aforementioned setting of the target value for the heating power, to the corresponding effect on the optical aberration (i.e. the influence on the effects of the so-called “mirror heating”) created as a result of incident used light during the actual operation of the optical element or the optical system comprising this element.

In other words, the disclosure can involve the concept that, in view of the issue (explained in the introduction) of opposing or conflicting desired properties with respect to firstly the temperature range favored for a correction of cold aberrations and secondly the temperature range favored for a compensation of the effects of “mirror heating”, just with the definition of the suitable target value or set of target values for the heating power introduced into the optical element by a thermal manipulator, both aspects “correction of cold aberrations” and “compensation of the effect of mirror heating” are already included.

In this case, the concept according to the disclosure for correcting cold aberrations differs from conventional approaches also using a thermal manipulator in that, for example, when defining the target value or set of target values for the heating power introduced for correction, consideration is already given to the effect thereof on the compensation, likewise provided, of the influence of “mirror heating” during the used operation of the optical element.

In embodiments of the disclosure, when defining the target value or set of target values for the heating power introduced for correction, a control (correction) of the heating power, which optionally occurs dependent on the EUV load during subsequent operation of the optical system, can also be taken. For example, this means that e.g. the difference between the set heating power from the zero-crossing temperature at the start of operation can be comparatively larger—in favor of an even further improved correction of cold aberrations—since the control (correction) with regard to the influence of “mirror heating”, which is added during operation, makes it possible to nevertheless maintain transient optical aberrations during operation of the optical system at an acceptable level.

According to one embodiment, setting the set of target values comprises a co-optimization of a deformation profile created by the thermal manipulator on the optical element with regard to both the first optical aberration and the second optical aberration.

According to one embodiment, the set of target values are set on the basis of a merit function for wavefront aberrations caused by the optical element, wherein this merit function is augmented by a term for taking into account the effect of introducing the heating power on the second optical aberration.

Here, the concept of minimizing a merit function for optimizing the heating power introduced into an optical element by a thermal manipulator, known per se, is augmented to the effect that the use of a suitable approach for this merit function leading to minimization of the latter already results in the desired co-optimization of the thermally induced deformation profile with regard to both the first optical aberration (=“cold aberration”) and the second optical aberration (=“mirror heating”).

According to one embodiment, the term for taking account of the effect of the introduction of the heating power on the second optical aberration is a regularization term, which is defined without explicit determination of wavefront aberrations caused by used light incident on the optical element during the operation of the optical system purely on the basis of prior knowledge concerning the thermal behavior of the optical element during the operation of the optical system.

The concept of a regularization of the merit function pursued according to the disclosure means that the introduction of a regularization term leads to certain solutions (for example, solutions with comparatively low heating power of the thermal manipulator) within the entire solution space being desirable over other solutions (e.g. those with comparatively high heating power of the thermal manipulator) from the outset. The regularization approach is further characterized in that the influence of thermal manipulation, brought about for the correction of cold aberrations, on the “mirror heating” or the compensation thereof can be kept to a minimum with the corresponding approach for the merit function to be minimized, without an explicit calculation of the second optical aberration or a determination of the explicit influence with regard to “mirror heating” being carried out in this respect.

According to one embodiment, the co-optimization is representable as:

$$\vec{{x}^{*}} , \vec{{h}^{*}} = arg {min}_{\vec{x} , \vec{h}} D ( s + l ( \vec{x} ) + f ( \vec{h} ) + P ( \vec{h} - {\vec{h}}_{ref} ) ) , \qquad ( 1 )$$

where \vec{x*} and \vec{h*} denote the result of co-optimization, l(\vec{x}) denotes the dependence of the wavefront effect on the position and orientation of the optical elements \vec{x}, S denotes the first optical aberration, f(\vec{h}) denotes the dependence of the wavefront effect on the heating power \vec{h} set by the thermal manipulator, P denotes a regularization term and \vec{h}_{ref} denotes a predetermined reference set of target values for the heating power.

The metric D specifies a rule for weighting individual aspects (e.g. Zernike coefficients) of the aberrations and the condensation of the entire wavefront information to a single scalar value.

The components of the vector quantities \vec{x} can denote the individual amplitudes of the rotational and translational manipulators of the optical element and \vec{h} can denote the respective heating loads of the individual thermal manipulators or sectors, with the result values co-optimized with regard to both quantities in each case being denoted by \vec{x*}, \vec{h*}.

According to another embodiment, the term for giving consideration to the effect of the introduction of the heating power on the second optical aberration is ascertained by explicit determination of wavefront aberrations caused by used light incident on the optical element during the operation of the optical system.

According to one embodiment, the co-optimization is representable as:

$$\vec{{x}^{*}} , \vec{{h}^{*}} = {arg min}_{\vec{x} , \vec{h}} ( D ( S + l ( \vec{x} ) + f ( \vec{h} ) ) + D ( G ( {Z}_{∞ , {UC}_{n}} ( \vec{h} ) ) ) ) , \qquad ( 2 )$$

where \vec{x*} and \vec{h*} denote the result of co-optimization, l(\vec{x}) denotes the dependence of the wavefront effect on the position and orientation of the optical elements \vec{x}, S denotes the first optical aberration, f(\vec{h}) denotes the dependence of the wavefront effect on the heating power \vec{h} set by the thermal manipulator and G(Z_{∞,UC}_{ₙ}(\vec{h}) denotes the second optical aberration in the thermal equilibrium state.

According to this—unlike the regularization described above—optical aberrations due to “mirror heating” are explicitly considered as part of the merit function for certain user scenarios UCₙ, in particular the aberrations due to “mirror heating” in the thermal equilibrium state Z_{∞,UC}_{ₙ}(\vec{h}). The second metric G (introduced in addition to the metric D) can in this case take into account a different weighting of different user scenarios or e.g. only a user scenario assessed as highly relevant with regard to “mirror heating”.

The separate combination by calculation of the initial state S+f(\vec{h}) and the “mirror heating” aberrations G(Z_{∞,UC}_{ₙ}(\vec{h})) with the metric D serves to rule out that the terms f(\vec{h}) and G(Z_{∞,UC}_{ₙ}(\vec{h})) mutually compensate each other. In other words, it should be ensured at the start of operation that the optical system or projection lens also provides a good wavefront or a wavefront corrected to the best possible extent with regard to manufacturing or alignment-related aberrations.

In further embodiments, use can alternatively be made of a merit function whose minimization optimizes the final state, wherein then the aforementioned exclusion of mutual compensation of the terms f(\vec{h}) and G(Z_{∞,UC}_{ₙ}(\vec{h})) is achieved by additional constraints. In this case, a set of M specifications of certain indicators (KPIᵢ) provides a suitable compensation or compromise between cold aberrations on the one hand and aberrations due to “mirror heating” on the other hand, which compensation or compromise is to be observed when minimizing the merit function:

$$\vec{{x}^{*}} , \vec{{h}^{*}} = {arg min}_{\vec{x} , \vec{h}} D ( S + l ( \vec{x} ) + f ( \vec{h} ) + G ( {Z}_{∞ , {UC}_{n}} ( \vec{h} ) ) ) \qquad ( 3 )$$

$$where$$

$${KPI}_{i} ( s + f ( \vec{h} ) ) < Spec ( {KPI}_{i} , cold ) , i ∈ M$$

$${KPI}_{i} ( G ( {Z}_{∞ , {UC}_{n}} ( \vec{h} ) ) ) < Spec ( {KPI}_{j} , MH ) i ∈ M .$$

According to one embodiment, the term for giving consideration to the effect of the introduction of the heating power on the second optical aberration is ascertained by explicit determination of the maximum in the temporal evolution of the wavefront aberrations caused by used light incident on the optical element during the operation of the optical system.

According to one embodiment, the co-optimization is representable as

$$\vec{{x}^{*}} , \vec{{h}^{*}} = {arg min}_{\vec{x} , \vec{h}} D ( S + l ( \vec{x} ) + f ( \vec{h} ) + G ( max ( {Z ( \vec{h} , t )}_{{UC}_{n}} ) ) ) , \qquad ( 4 )$$

where \vec{x*} and \vec{h*} denote the result of co-optimization, S denotes the first optical aberration, l(\vec{x}) denotes the dependence of the wavefront effect on the position and orientation of the optical elements x, f(\vec{h}) denotes the dependence of the wavefront effect on the heating power \vec{h} set by the thermal manipulator and

$$G ( max ( {Z ( \vec{h} , t )}_{{UC}_{n}} ) )$$

denotes the maximum in the temporal evolution of the second optical aberration.

The explicit determination or consideration of the maximum in the temporal evolution of the wavefront aberrations caused by used light incident on the optical element during operation can serve to ensure that “overshoots” in the temporal evolution of the aberrations caused by “mirror heating” are minimized. This co-optimization of the cold aberrations and the aberrations caused by “mirror heating” while taking into account the maximum time already can ensure that the optical system or projection lens has minimal overall aberrations at the start of operation.

Thus, in this case, the merit function takes only the state

$$S + l ( \vec{x} ) + f ( \vec{h} ) + G ( max ( {Z ( \vec{h} , t )}_{{UC}_{n}} ) )$$

into consideration.

Analogously to the aforementioned embodiment, this merit function can also be augmented by additional constraints to ensure that respective individual specifications are observed for the cold aberrations on the one hand and the aberrations due to “mirror heating” on the other hand. For systems in which the co-optimization according to the disclosure has already been carried out taking into account the thermal equilibrium state but in which the maximum of the temporal evolution of the aberrations due to “mirror heating” does not coincide with the thermal equilibrium state, the co-optimization enables an even better imaging quality of the projection lens while taking into account the maximum over time of the aberrations caused by “mirror heating”.

A development of the present disclosure involves an additional optimization of the zero-crossing temperature ZCT of the substrate of the optical element.

This zero-crossing temperature can be reproducibly set within certain limits by material manufacturers on the basis of specifications. Suitable selection of the ZCT allows the co-optimization according to the disclosure with regard to cold aberrations and mirror heating to be further improved.

To avoid mirror heating effects, the average temperature target value during operation was until now usually selected near the ZCT in order to generate mirror heating aberrations that are as small as possible. In the context of the disclosure, however, this target value generally no longer coincides with the ZCT because a sufficient correction of the cold aberrations by thermal manipulators is only possible away from the ZCT.

Therefore, selecting an optimal ZCT is not trivial in the context of the present disclosure, and one embodiment of the disclosure accordingly proposes that the co-optimization additionally comprises the zero-crossing temperature or ZCT of a substrate material of the optical element as the quantity to be optimized, whereby an optimized zero-crossing temperature ZCT is ascertained as a specification for the design of the substrate material.

In principle, the above-described optimization strategies are each augmented by one parameter ZCT.

To take into account that the ZCT should not be varied arbitrarily and that there generally are desired temperature operating ranges, the co-optimization with the ZCT as parameter to be optimized can be carried out using a regulation or penalty term P that depends on a predetermined temperature target value \vec{h_{ref}}(ZCT).

This penalty term describes the implicit consideration of MH aberrations in the optimization in the event of a lack of basic knowledge for quantifying the MH aberrations, for example if unlike the source power, which is known, the intensity distribution on the optical element is not known.

A corresponding (usually numerically solved) co-optimization rule that takes into account the ZCT as a parameter to be optimized is thus representable as:

$$\vec{{x}^{*}} , \vec{{h}^{*}} , {ZCT}^{*} = {arg min}_{X , ZCT} D ( S + l ( \vec{x} ) + f ( \vec{h} , ZCT ) ) + P ( \vec{h} - \vec{{h}_{ref}} ( ZCT ) ) , \qquad ( 5 )$$

where \vec{x*} represent the optimal amplitudes of the rotational and translational manipulators, \vec{h*} represent the optimal amplitudes of the thermal manipulators and ZCT* represents the optimal ZCT as a result of the co-optimization, S represents the cold aberration, l(\vec{x}) represents the dependence of the wavefront effect on the position and orientation of the optical elements \vec{x}, f(\vec{h},ZCT) represents the wavefront-dependent correction of same, P represents a regulation term dependent on a predetermined target value \vec{h_{ref}}(ZCT) desirable for mirror heating and D represents a scalar metric.

In analogy to equation (2) above, the co-optimization taking into account the ZCT as a parameter to be optimized can also be represented taking into account the thermal equilibrium state (steady state) as part of the merit function, as follows:

$$\vec{{x}^{*}} , \vec{{h}^{*}} , {ZCT}^{*} = {arg min}_{X , ZCT} D ( S + l ( \vec{x} ) + f ( \vec{h} , ZCT ) ) + D ( G ( {Z}_{∞ , {UC}_{n}} ( \vec{h} , ZCT ) ) ) , \qquad ( 6 )$$

where \vec{x*} represent the optimal amplitudes of the rotational and translational manipulators, \vec{h*} represent the optimal amplitudes of the thermal manipulators and ZCT* represents the optimal ZCT as a result of the co-optimization, S represents the cold aberration, l(\vec{x}) represents the dependence of the wavefront effect on the position and orientation of the optical elements \vec{x}, f(\vec{h},ZCT) represents the wavefront-dependent correction of same, Z_{∞,UC}_{ₙ}(\vec{h},ZCT) represents the mirror heating-related second optical aberration in the thermal equilibrium state following a correction by position and orientation of the optical elements, G represents a weighting metric and D represents a scalar metric.

Separate application of the metric D to both terms avoids the case that the optimization results in compensation of the two terms; this ensures that the optical unit also has a good wavefront at the start of operation. Alternatively—in a manner analogous to equation (4) above—a co-optimization taking into account the ZCT as a parameter to be optimized and taking into account the maximum over the entire transient time series is representable as:

$$\vec{{x}^{*}} , \vec{{h}^{*}} , {ZCT}^{*} = {arg min}_{X , ZCT} D ( S + l ( \vec{x} ) + f ( \vec{h} , ZCT ) ) + D ( max G ( {Z}_{{UC}_{n}} ( \vec{h} , ZCT ) ) ) , \qquad ( 7 )$$

where \vec{x*} represent the optimal amplitudes of the rotational and translational manipulators, \vec{h*} represent the optimal amplitudes of the thermal manipulators and ZCT* represents the optimal ZCT as a result of the co-optimization, S represents the cold aberration, l(\vec{x}) represents the dependence of the wavefront effect on the position and orientation of the optical elements \vec{x}, f(\vec{h},ZCT) represents the wavefront-dependent correction of same, Z_{UC}_{ₙ}(\vec{h},ZCT) represents the mirror heating-related second optical aberration following a transient correction by position and orientation of the optical elements, G represents a weighting metric and D represents a scalar metric.

The weighting metric G condenses the mirror heating term into a scalar. Specifically, it depends on the specific mirror heating use cases.

The numerical solution of the equations (5)-(7) can be achieved via a nested optimization with an outer iteration loop or an outer loop, in which sampling is carried out over a ZCT range, and an inner iteration loop, or an inner loop, in which cold and MH aberrations are co-optimized for each ZCT.

For further details, reference is made to the above statements regarding equations (1) to (4).

As already mentioned, the scope of the disclosure can provide for an ascertained optimized temperature target value for the optical element to not coincide with the ZCT of the substrate material of the optical element.

According to one embodiment, the optical element is heated in such a way that a spatial and/or temporal variation of a temperature distribution in the optical element is reduced.

According to one embodiment, the optical element is a mirror.

According to one embodiment, the optical element is designed for an operating wavelength of less than 400 nm, such as less than 250 nm, for example less than 200 nm.

According to one embodiment, the optical element is designed for an operating wavelength of less than 30 nm, such as less than 15 nm.

The disclosure further also relates to an optical system, in particular in a microlithographic projection exposure apparatus, comprising
at least one optical element,
a thermal manipulator for heating this optical element,
a control unit for setting, on the basis of a set of target values, the heating power introduced into the optical element by the heating arrangement, and
a target value generator for generating the set of target values for creating a thermally induced deformation, wherein the set of target values is set depending on a first optical aberration to be compensated, additionally taking into account the respective effect of introducing the heating power on a second optical aberration, which is caused by used light incident on the optical element during operation of the optical system.

According to one embodiment, the first optical aberration is at least partly caused by manufacturing or alignment.

According to one embodiment, the ZCT of a substrate of the optical element is co-optimized with regard to a cold aberration to be compensated by the thermal manipulators while simultaneously minimizing mirror heating aberrations on the optical element expected during the operation of the optical system, as already explained above in detail. The optical element can then be manufactured on the basis of the ZCT co-optimized thus.

According to one embodiment, the optical system is configured to carry out a method having the features described above. With regard to features and aspects of the optical system, reference is made to the abovementioned explanations in association with the method according to the disclosure.

Further configurations of the disclosure can be gathered from the description and the claims.

The disclosure is elucidated in further detail hereinafter with reference to exemplary embodiments shown in the appended figures.

### BRIEF DESCRIPTION OF THE DRAWINGS

In the figures:

FIG. 1 shows a schematic illustration of the possible setup of a microlithographic projection exposure apparatus designed for operation in the EUV;

FIG. 2 shows a diagram for elucidating a basic issue relating the present disclosure;

FIGS. 3-5 show diagrams illustrating the mode of action of the present disclosure; and

FIG. 6 shows a diagram explaining a ZCT co-optimization.

### DETAILED DESCRIPTION

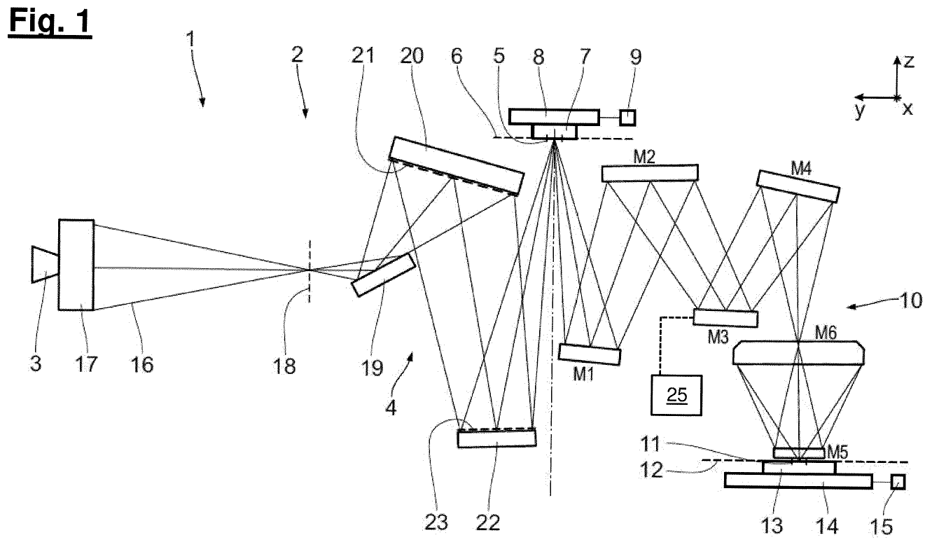

FIG. 1 shows a schematic illustration of a projection exposure apparatus 1 which is designed for operation in the EUV and in which the disclosure is realizable by way of example.

According to FIG. 1, the projection exposure apparatus 1 comprises an illumination device 2 and a projection lens 10. The illumination device 2 serves to illuminate an object field 5 in an object plane 6 with radiation from a radiation source 3 by way of an illumination optical unit 4. What is exposed here is a reticle 7 arranged in the object field 5. The reticle 7 is held by a reticle holder 8. The reticle holder 8 is displaceable via a reticle displacement drive 9, in particular in a scanning direction. For explanation purposes, a Cartesian xyz-coordinate system is depicted in FIG. 1. The x-direction runs perpendicularly to the plane of the drawing into the latter. The y-direction runs horizontally, and the z-direction runs vertically. The scanning direction runs in the y-direction in FIG. 1. The z-direction runs perpendicularly to the object plane 6.

The projection lens 10 serves for imaging the object field 5 into an image field 11 in an image plane 12. A structure on the reticle 7 is imaged on a light-sensitive layer of a wafer 13 arranged in the region of the image field 11 in the image plane 12. The wafer 13 is held by a wafer holder 14. The wafer holder 14 is displaceable by way of a wafer displacement drive 15 such as in the y-direction. The displacement, firstly, of the reticle 7 by way of the reticle displacement drive 9 and, secondly, of the wafer 13 by way of the wafer displacement drive 15 can be synchronized with one another.

The radiation source 3 is an EUV radiation source. The radiation source 3 emits EUV radiation, which is also referred to below as used radiation or illumination radiation. For example, the used radiation has a wavelength in the range of between 5 nm and 30 nm. The radiation source 3 can be for example a plasma source, a synchrotron-based radiation source or a free electron laser (FEL). The illumination radiation 16 emanating from the radiation source 3 is focused by a collector 17 and propagates through an intermediate focus in an intermediate focal plane 18 into the illumination optical unit 4. The illumination optical unit 4 comprises a deflection mirror 19 and, arranged downstream thereof in the beam path, a first facet mirror 20 (having schematically indicated facets 21) and a second facet mirror 22 (having schematically indicated facets 23).

The projection lens 10 comprises a plurality of mirrors Mi (i=1, 2, . . . ), which are consecutively numbered according to their arrangement in the beam path of the projection exposure apparatus 1. In the example illustrated in FIG. 1, the projection lens 10 comprises six mirrors M1 to M6. Alternatives with four, eight, ten, twelve or a different number of mirrors Mi are also possible. The penultimate mirror M5 and the last mirror M6 each have a through opening for the illumination radiation 16. The projection lens 10 is a doubly obscured optical unit. The projection lens 10 has an image-side numerical aperture which, merely by way of example, may be greater than 0.3, and for example may also be greater than 0.5, for example greater than 0.6.

During operation of the microlithographic projection exposure apparatus 1, the electromagnetic radiation incident on the optical effective surface of the mirrors is partially absorbed and, as explained in the introduction, results in heating and an associated thermal expansion or deformation, which in turn can result in an impairment of the imaging properties of the optical system. By way of a thermal manipulator in the form of a heating arrangement, as described in the introduction, active mirror heating can then take place in each case in phases of comparatively low absorption of EUV used radiation, the active mirror heating being correspondingly decreased as the absorption of the EUV used radiation increases.

A heating arrangement is depicted merely schematically in FIG. 1 and denoted by “25”, this heating arrangement 25 being used to introduce a heating power into the mirror M3 in the example.

In this case, the disclosure is not further restricted with regard to the way in which heating power is introduced or the configuration of the heating arrangement used to this end. Purely by way of example, the heating power can be introduced in a manner known per se by way of infrared emitters or else by way of electrodes to which a voltage can be applied and which are arranged on the optical element or mirror to be heated.

Furthermore, the disclosure is not further restricted with regard to the number of optical elements or mirrors to be heated, with the result that the setting of target values of the heating power according to the disclosure can be applied to the heating of only a single optical element or else to the heating of a plurality of optical elements.

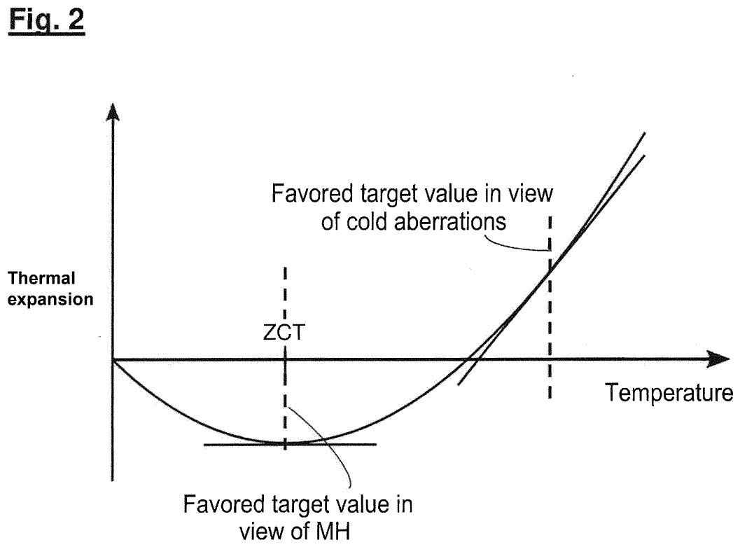

According to the disclosure and in view of the issue (explained in the introduction on the basis of FIG. 2) of opposing or conflicting desired properties with respect to firstly the temperature range favored for a correction of cold aberrations and secondly the temperature range favored for a compensation of the effects of “mirror heating”, both aspects of “correction of cold aberrations” and “compensation of mirror heating” are now included just with the definition of a set of target values for the heating power introduced into the optical element by a thermal manipulator. This is in turn achieved by virtue of already taking the corresponding effect on the optical aberration that is generated during the actual operation of the optical element or optical system comprising this element as a result of incident used light into account, especially by way of a “co-optimization” with minimization of a suitable merit function, e.g. according to the aforementioned approaches according to equations (1)-(4), in addition to the correction of the aforementioned “cold aberrations” when setting the heating power.

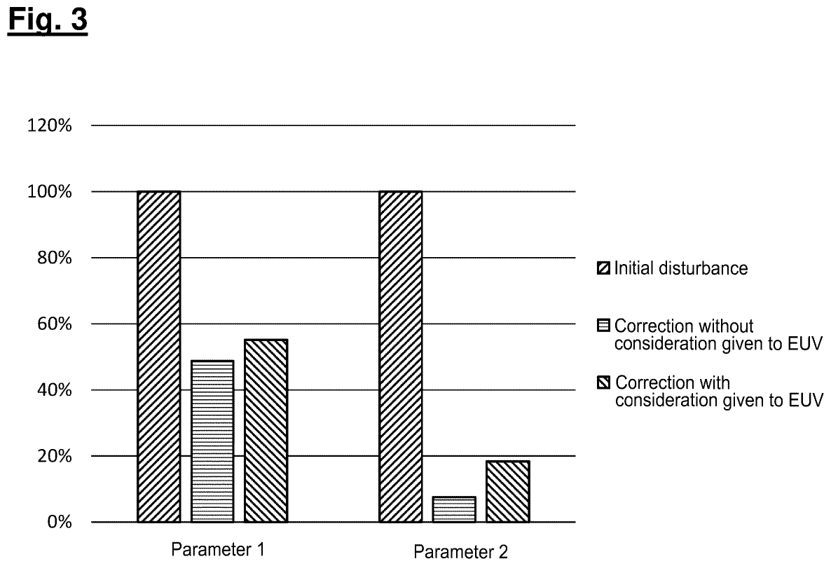

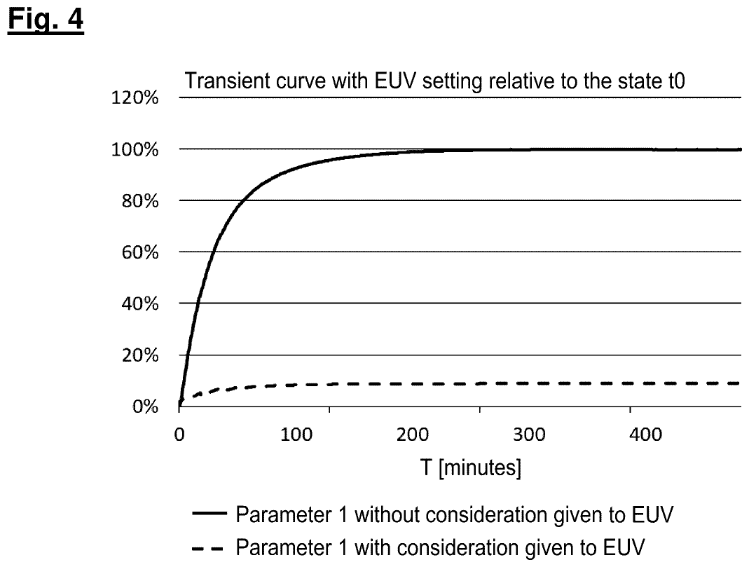

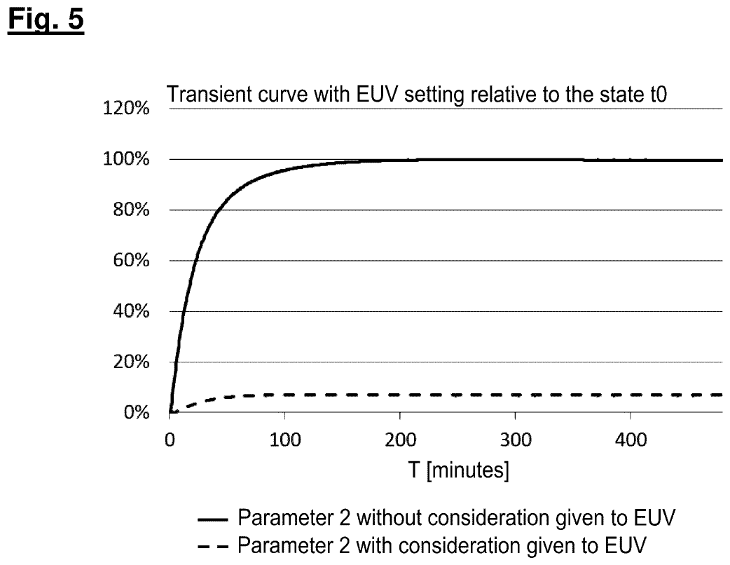

FIGS. 3-5 show diagrams illustrating the mode of action of the present disclosure. In this case, FIG. 4 and FIG. 5 depict the transient curve of exemplary parameters, which describe partial aspects of the optical aberrations and the wavefront, after operation is started under EUV load, to be precise for comparison of both the case without application of the co-optimization according to the disclosure (=solid line in FIG. 4 and FIG. 5) and the case with application of the co-optimization according to the disclosure (=dashed line in FIG. 4 and FIG. 5). It is evident from FIG. 4 and FIG. 5 that the aberrations due to the “mirror heating” can be significantly reduced as a result of the co-optimization according to the disclosure or the compromise set in this case with regard to the correction of the aforementioned “cold aberrations” and the compensation of the effects of “mirror heating”. At the same time, the diagram of FIG. 3 shows that this effect is achieved without any appreciable impairment in the achieved correction of the cold aberrations.

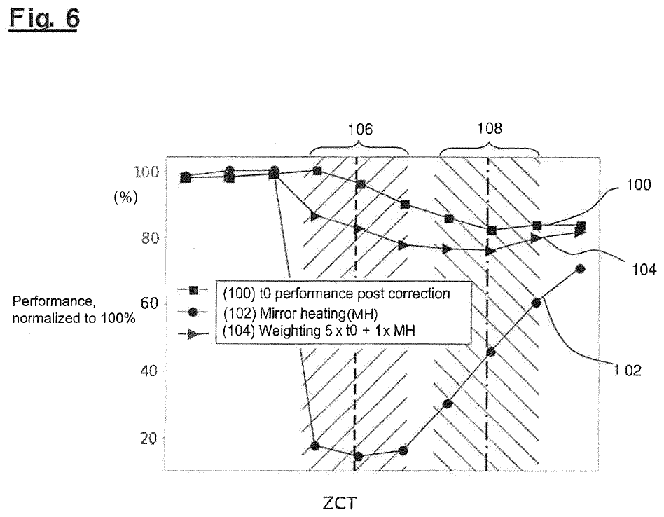

To illustrate the optional ZCT optimization, the diagram in FIG. 6 shows performance quantities normalized to a maximum for a so-called t₀ correction residual (cold aberration correction) with sector heaters (curve 100) and a mirror heating (curve 102), based thereon, for a mirror over various mean ZCT values.

In this illustration, lower performance values represent lower aberrations, and so the sought-after goal lies in minimizing the corresponding graphs.

In this example—without loss of generality—it is evident that the desired ZCT would be at the minimum of curve 100 if only the aspect of mirror heating were taken into account.

This ZCT plus a certain tolerance band would have been chosen to date (region 106 around the dashed line).

However, it is evident that the to correction works better at higher ZCT values.

For example, if the to correction were weighted with a factor of 5—these are ultimately prioritization assumptions—w.l.o.g., then this would result in an overlaid curve 104—calculated using the rule 5×t₀+1×MH—with a minimum at a higher temperature value.

This would yield an alternative tolerance band (region 108) that would provide the best ZCT for both to and mirror heating under the given boundary conditions.

By co-optimizing the ZCT, this target ZCT can be determined and taken into account in the manufacture of the optical element.

Even though the disclosure has been described on the basis of specific embodiments, numerous variations and alternative embodiments are evident to a person skilled in the art, e.g. through combination and/or exchange of features of individual embodiments. Accordingly, it will be apparent to the person skilled in the art that such variations and alternative embodiments are also encompassed by the present disclosure, and the scope of the disclosure is restricted only within the scope of the appended patent claims and equivalents thereof.

What is claimed is:

1. A method of using a thermal manipulator to heat an optical element in an optical system, the method comprising:
setting a heating power of the thermal manipulator to a set of target values to create a thermally induced deformation of the optical element, the set of target values being based on:
i) on a first optical aberration of the optical system to be compensated by heating the optical element using the thermal manipulator;
ii) an effect of introducing the heating power into the optical element on a second optical aberration caused by used light incident on the optical element during operation of the optical system; and
iii) a co-optimization of a deformation profile of the optical element created by heat introduced to the optical element by the thermal manipulator with regard to both the first and second optical aberrations; and
introducing the heating power at the set of target values into the optical element.

2. The method of claim 1, wherein the first optical aberration is at least partly caused by manufacturing or alignment.

3. The method of claim 1, wherein the set of target values are further based on iv) a merit function for wavefront aberrations caused by the optical element, and the merit function is augmented by a term that takes into account the effect of introducing the heating power on the second optical aberration.

4. The method of claim 3, wherein the term is a regularization term defined without explicit determination of wavefront aberrations caused by used light incident on the optical element during the operation of the optical system only on the basis of prior knowledge concerning thermal behavior of the optical element during the operation of the optical system.

5. The method of claim 1, wherein the co-optimization is represented as
$$\vec{{x}^{*}} , \vec{{h}^{*}} = {arg min}_{\vec{x} , \vec{h}} D ( S + l ( \vec{x} ) + f ( \vec{h} ) + P ( \vec{h} - {\vec{h}}_{ref} ) ) ,$$
where \vec{x*} and \vec{h*} denote the result of co-optimization, S denotes the first optical aberration, l(\vec{x}) denotes a dependence of the wavefront effect on a position and an orientation of optical elements \vec{x}, f(\vec{h}) denotes a dependence of a wavefront effect on the heating power set by the thermal manipulator, P denotes a regularization term, \vec{h}_{ref} denotes a predetermined reference set of target values for the heating power, and D denotes a scalar metric function.

6. The method of claim 3, further comprising determining the term by explicitly determining wavefront aberrations caused by used light incident on the optical element during the operation of the optical system.

7. The method of claim 6, wherein the co-optimization is represented as
$$\vec{{x}^{*}} , \vec{{h}^{*}} = {arg min}_{\vec{x} , \vec{h}} ( D ( S + l ( \vec{x} ) + f ( \vec{h} ) ) + D ( G ( {Z}_{∞ , {UC}_{n}} ( \vec{h} ) ) ) )$$
where \vec{x*} and \vec{h*} denote a result of co-optimization, S denotes the first optical aberration, l(\vec{x}) denotes a dependence of a wavefront effect on a position and an orientation of optical elements \vec{x}, f(\vec{h}) denotes the dependence of the wavefront effect on the heating power \vec{h} set by the thermal manipulator, and G(Z_{∞,UC}_{ₙ}(\vec{h})) denotes the second optical aberration in a thermal equilibrium state following the correction by the position and the orientation of the optical elements.

8. The method of claim 3, further comprising determining the term by explicitly determining a maximum in a temporal evolution of wavefront aberrations caused by used light incident on the optical element during operation of the optical system.

9. The of claim 8, wherein the co-optimization is represented as
$$\vec{{x}^{*}} , \vec{{h}^{*}} = {arg min}_{\vec{x} , \vec{h}} D ( S + l ( \vec{x} ) + f ( \vec{h} ) + G ( max ( {Z ( \vec{h} , t )}_{{UC}_{n}} ) ) )$$
where \vec{x*} and \vec{h*} denote the result of co-optimization, S denotes the first optical aberration, l(\vec{x}) denotes a dependence of a wavefront effect on the position and orientation of optical elements \vec{x}, f(\vec{h}) denotes the dependence of the wavefront effect on the heating power set by the thermal manipulator and
$$G ( max ( {Z ( \vec{h} , t )}_{{UC}_{n}} ) )$$
denotes a maximum in a temporal evolution of the second optical aberration following a transient correction by the position and the orientation of the optical elements.

10. The method of claim 1, wherein the co-optimization additionally comprises a zero-crossing temperature of a substrate material of the optical element as a quantity to be optimized, whereby an optimized zero-crossing temperature is determined as a specification for a design of the substrate material.

11. The method of claim 10, wherein a regulation term P that depends on a predetermined temperature target value \vec{h_{ref}}(ZCT) is taken into account in the co-optimization with zero-crossing temperature as parameter to be optimized.

12. The method of claim 11, wherein the co-optimization with consideration of zero-crossing temperature as parameter to be optimized is represented as:
$$\vec{{x}^{*}} , \vec{{h}^{*}} , {ZCT}^{*} = {arg min}_{X , ZCT} D ( S + l ( \vec{x} ) + f ( \vec{h} , ZCT ) ) + P ( \vec{h} - \vec{{h}_{ref}} ( ZCT ) ) ,$$
where \vec{x*} represent optimal amplitudes of rotational and translational manipulators, \vec{h*} represent optimal amplitudes of thermal manipulators, ZCT* represents the optimal zero-crossing temperature as a result of the co-optimization, S represents a cold aberration, l(\vec{x}) represents a dependence of a wavefront effect on a position and orientation of optical elements \vec{x}, f(\vec{h}, ZCT) represents a wavefront-dependent correction of same, P represents a regulation term dependent on a predetermined target value \vec{h_{ref}}(ZCT) desirable for mirror heating, and D represents a scalar metric.

13. The method of claim 11, wherein the co-optimization with consideration of zero-crossing temperature as parameter to be optimized is represented as:
$$\vec{{x}^{*}} , \vec{{h}^{*}} , {ZCT}^{*} = {arg min}_{X , ZCT} D ( S + l ( \vec{x} ) + f ( \vec{h} , ZCT ) ) + D ( G ( {Z}_{∞ , {UC}_{n}} ( \vec{h} , ZCT ) ) ) ,$$
where \vec{x*} represent optimal amplitudes of rotational and translational manipulators, \vec{h*} represent optimal amplitudes of thermal manipulators, ZCT* represents an optimal zero-crossing temperature as a result of the co-optimization, S represents a cold aberration, l(\vec{x}) represents a dependence of a wavefront effect on the position and orientation of the optical elements \vec{x}, f(\vec{h}, ZCT) represents the wavefront-dependent correction of same, Z_{∞,UC}_{ₙ}(\vec{h}, ZCT) represents a mirror heating-related second optical aberration in a thermal equilibrium state following a correction by position and orientation of the optical elements, G represents a weighting metric, and D represents a scalar metric.

14. The method of claim 11, wherein the co-optimization with consideration of zero-crossing tempertuare as parameter to be optimized is represented as:
$${X}^{*} , {ZCT}^{*} = {arg min}_{X , ZCT} D ( S + l ( \vec{x} ) + f ( \vec{h} , ZCT ) ) + D ( max G ( {Z}_{{UC}_{n}} ( \vec{h} , ZCT ) ) ) ,$$
where \vec{x*} represent optimal amplitudes of rotational and translational manipulators, \vec{h*} represent optimal amplitudes of thermal manipulators, ZCT* represents the optimal zero-crossing temperature as a result of the co-optimization, S represents a cold aberration, l(\vec{x}) represents a dependence of a wavefront effect on the position and orientation of optical elements \vec{x}, f(\vec{h}, ZCT) represents the wavefront-dependent correction of same, Z_{UC}_{ₙ}(\vec{h}, ZCT) represents a mirror heating-related second optical aberration following a transient correction by position and orientation of the optical elements, G represents a weighting metric, and D represents a scalar metric.

15. The method of claim 1, wherein an ascertained optimized temperature target value for the optical element does not coincide with the zero-crossing temperature of a substrate material of the optical element.

16. The method a of claim 1, wherein the optical element is heated to reduce a spatial variation of a temperature distribution in the optical element and/or a temporal variation of a temperature distribution in the optical element.

17. The method of claim 1, wherein the optical element comprises a mirror.

18. The method of claim 1, wherein the optical element is configured to be used at an operating wavelength of less than 400 nanometers.

19. The method of claim 1, wherein the optical element is configured to be used at an operating wavelength of less than 30 nanometers.

20. The method of claim 1, wherein the optical system is a microlithographic projection exposure apparatus.

21. An optical system, comprising:
an optical element;
a thermal manipulator configured to heat the optical element;
a control unit configured to set a heating power of the thermal manipulator to a set of target values to create a thermally induced deformation of the optical element, the set of target values being based on:
i) on a first optical aberration of the optical system to be compensated by heating the optical element using the thermal manipulator;
ii) an effect of introducing the heating power into the optical element on a second optical aberration caused by used light incident on the optical element during operation of the optical system; and
iii) a co-optimization of a deformation profile of the optical element created by heat introduced to the optical element by the thermal manipulator with regard to both the first and second optical aberrations.

22. The optical system of claim 21, wherein the optical system is a microlithographic projection exposure apparatus.
